(19) United States
(12) Patent Application Publication
(10) Pub. No.: US 2024/0184944 A1
(43) Pub. Date: Jun. 6, 2024

(54) AUTOMATIC IDENTIFICATION OF MISSING VALUE PATTERNS FOR DIGITAL TWIN RESILIENCE SUPPORT

(71) Applicant: Dell Products L.P., Round Rock, TX (US)

(72) Inventors: Herberth Birck Fröhlich, Florianópolis (BR); Vinicius Michel Gottin, Rio de Janeiro (BR)

(21) Appl. No.: 18/048,566

(22) Filed: Oct. 21, 2022

(51) Int. Cl. G06F 30/20; G06F 17/16

(52) U.S. Cl. CPC G06F 30/20; G06F 17/16

(57) ABSTRACT

Missing value patterns are automatically identified, and the missing values are imputed. Historical observations are searched for loss patterns, which include block loss patterns and row loss patterns. The loss patterns identified from the historical observations are used to find losses in online observations. Missing values are imputed using an imputation method that is selected based on the loss pattern.

### FIELD OF THE INVENTION

Embodiments of the present invention generally relate to digital twin systems and digital twin operations. More particularly, at least some embodiments of the invention relate to systems, hardware, software, computer-readable media, and methods for automatically identifying and missing value patterns and/or imputing values in the context of digital twins.

### BACKGROUND

A digital twin is, in one example, a virtual system that represents a physical system. The digital twin is a digital model of a physical entity. Digital twins are often used during both development and usage scenarios. The resilience of a digital twin is the capability of the digital twin to operate and maintain an acceptable level of service when disrupted. This may include the ability to recover lost capacity in a timely manner or to reassign workloads and functions.

Digital twins may be disrupted when they lose signals or signal values that are needed for execution. For example, the loss of a signal from a sensor is referred to as sensor drop off. Sensor drop off can severely impact the operation of a digital twin and may make the output of the digital twin unreliable.

When sensor drop off is small, a trivial solution is to ignore the missing values. This can, however, reduce the quality of the data and lead to bias or other concerns. If the sensor drop off is more significant or frequent, the reliability of the digital twin system can degrade significantly.

### BRIEF DESCRIPTION OF THE DRAWINGS

In order to describe the manner in which at least some of the advantages and features of the invention may be obtained, a more particular description of embodiments of the invention will be rendered by reference to specific embodiments thereof which are illustrated in the appended drawings. Understanding that these drawings depict only typical embodiments of the invention and are not therefore to be considered to be limiting of its scope, embodiments of the invention will be described and explained with additional specificity and detail through the use of the accompanying drawings, in which:

FIG. 1 discloses aspects of a digital twin framework or system;

FIG. 2 discloses aspects of loss patterns;

FIG. 3 discloses aspects of an offline stage configured to identify relevant loss patterns;

FIG. 4A discloses aspects of sensor data or sensor observations;

FIG. 4B discloses aspects of binarized observations and illustrates an example of evaluating the binarized observations using matrices;

FIG. 4C discloses aspects of iterating a window over binarized observations in a matrix;

FIG. 4D discloses aspects of pseudocode configured to identify relevant loss patterns;

FIG. 4E discloses additional aspects of identifying relevant loss patterns in a set of observations;

FIG. 5A discloses aspects of identifying row loss patterns with different allowable gap values;

FIG. 5B discloses additional aspects of identifying row loss patterns;

FIG. 6 discloses aspects of an online stage for finding loss patterns and/or imputing values that may be missing; and

FIG. 7 discloses aspects of a computing device, system, or entity.

### DETAILED DESCRIPTION OF SOME EXAMPLE EMBODIMENTS

Embodiments of the present invention generally relate to digital twin systems and digital twin operations. More particularly, at least some embodiments of the invention relate to systems, hardware, software, computer-readable media, and methods for increasing the resilience of digital twins using signal imputation based on the recognition of missing values patterns.

Embodiments of the invention more specifically relate to digital twin operations including signal imputation operations, pattern recognition operations, missing values pattern recognition, or the like or combinations thereof.

In one example, a data imputation pipeline is disclosed. The data imputation pipeline may include various stages, which include an offline stage and an online stage. The offline stage may evaluate historical observations (e.g., data such as signal outputs, measurements, or values) and identify loss patterns in the observations. Loss may include missing, noisy, and/or wrong values.

By identifying or finding patterns of missing values, the method used for data imputation can be determined or selected. Embodiments of the invention are configured to detect patterns of data loss in an efficient and/or online manner, which allows imputation method to be identified and executed.

In one example, finding patterns of missing values may use historical data that is missing values. Signal losses may exist in the historical data and/or may be artificially inputted if, for example, the drop off modes are known. This builds on the assumption that the losses reflect the possible losses that occur during operations of the data sources (e.g., sensors).

Patterns may be identified during an offline stage by searching the historical data. This allows the parameters of relevant loss patterns to be identified and may also identify a possible window size and/or matrix size for online pattern recognition. In one example, relevant loss patterns include patterns selected during the offline stage and used during the online stage of the imputation pipeline.

During the online stage, the patterns learned during the offline state allow patterns in the online stage to be recognized or identified. The output of a pattern recognition engine is to identify one or more missing value patterns, which are provided to and used by the online stage of the data imputation pipeline. This aids the choice of selecting an imputation method.

Detecting multiple patterns, however, is a challenging task even assuming that classes of sensor loss patterns are known. More specifically, the kinds of patterns that are typical or common in a given domain are not known in advance. Loss patterns in one domain may differ from loss patterns in other domains. Further, the duration of losses is variable, and any time window needed to consider or identify patterns is not trivially known. Larger time windows may allow for more patterns, which may help in selecting a data imputation method, but may adversely impact online pattern recognition.

Embodiments of the invention improve the resilience of a digital twin such that pattern detection can be accomplished efficiently in the absence of sensor signals or sensor values or portions thereof.

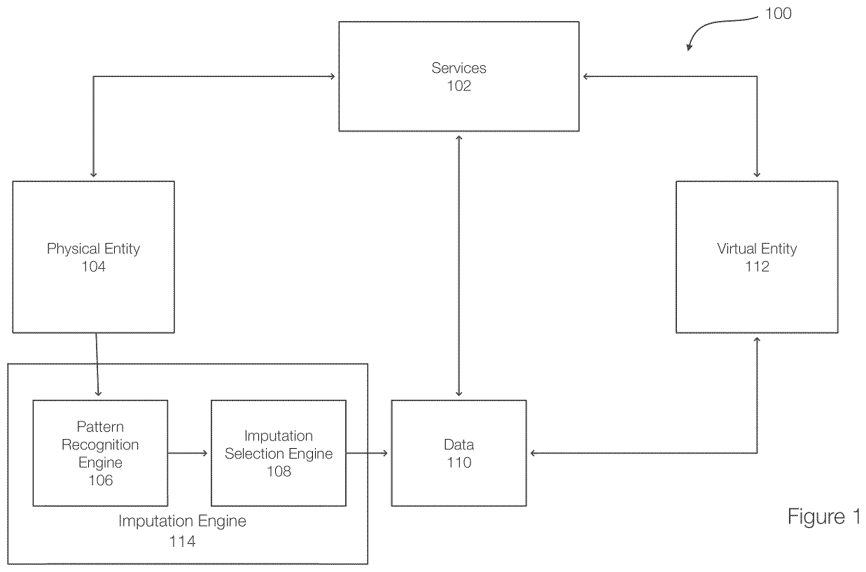

In one example, a digital framework may include five dimensions: physical entity, virtual entity, services, connection, and digital data. FIG. 1 discloses aspects of a digital twin framework or system. The digital twin system 100 include a physical entity 104. The physical entity 104 may include various systems, subsystems and sensory devices, such as, but not limited to, a dynamic system, a control system, a hydraulic system, sensors, design, manufacturing, or the like. The virtual entity 112 (the digital twin) is a mirror of the physical entity 104 and may include geometry models, physics models, behavior models, rule modes, or the like or combination thereof.

The services 102 are configured to ensure that the physical entity 104 operates as expected and sustains high-fidelity of the virtual entity 112 through model parameters calibration. For the physical entity 104, the services 102 may include monitoring, state prediction, optimization, or the like. For the virtual entity 112, the services may include construction services, calibration services, test service models, and the like. The connections represent possible connections, which may be bidirectional, between the services 102, the physical entity 104, the virtual entity 112, and data 110. The data 110 may be a data base that stores data from the physical entity 104, the virtual entity 112, from services 102, and fusions or combinations thereof.

FIG. 1 further illustrates aspects of an imputation pipeline 114, which includes a pattern recognition engine 106 and an imputation selection engine 108. As illustrated, the pattern recognition engine 106 may be configured to check all signals (e.g., observations from sensors of the physical entity 104). This allows missing values in the data to be imputed, for example prior to storage or use. The method of imputation is selected by the imputation selection engine 108.

During an offline state, the imputation pipeline 114 may learn loss patterns using historical data. During an online stage, the missing patterns in the observations are found or identified and missing values are imputed using a selected imputation method.

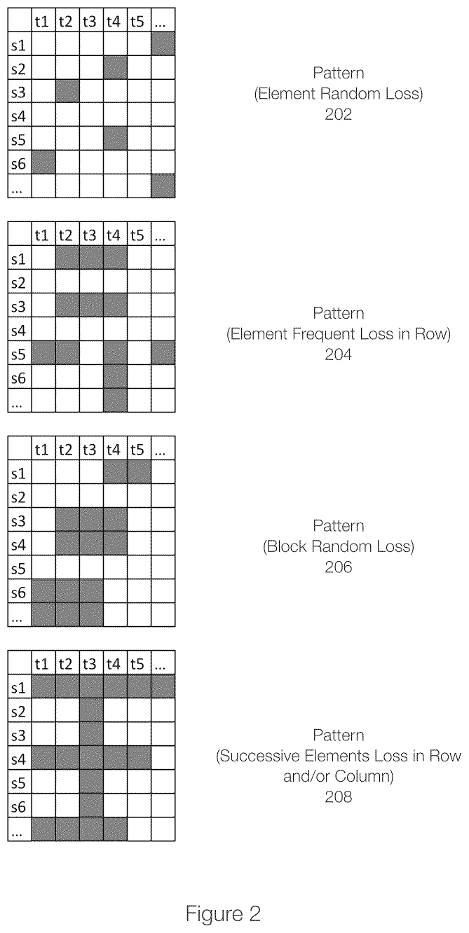

FIG. 2 discloses aspects of example loss patterns. FIG. 2 illustrates examples of an element random loss pattern 202, an element frequent loss in rows pattern 204, a block random loss pattern 206, and a successive elements loss in row and/or column pattern 208. In example embodiments, patterns may include these patterns and/or combinations thereof. Embodiments of the invention are not limited to detecting the patterns illustrated in FIG. 2.

The pattern 202 (single element random loss) is comparatively easier to detect. The imputation methods for the patterns 202 may include replacing the missing values with an average of the previous observation (or sample), reusing the value of the last valid observation, or the like. The imputation method may depend on the nature of the observation.

The pattern 208 (successive element loss in whole row or columns) is also comparatively easier to detect and values can be imputed in a similar manner such as using the most recent value, or an average of one or more previous valid values. A whole column loss suggests that no data was available at a certain time sample. A whole row loss suggests that no data from a particular sensor was available or detected. These patterns can be detected by simple if-then rules. Further these patterns can be detected during the online stage of pattern detection. No preprocessing is required to make the discovery of the patterns 202 and/or 208 (or similar patterns) easier or more efficient in one example.

An offline stage of the pattern recognition engine 106 may be performed for patterns such as the patterns 204 and 206. With regard to the pattern 204, in one embodiment, a minimum number of valid signals may be required to “break” a consecutive loss pattern before such a pattern is detected. Embodiments of the invention may determine the minimum instance of the pattern that should be searched for or checked during the online stage. For example, a minimum number of gaps may be used in detecting element frequent loss in row patterns.

The pattern 206 (the block random loss) has additional dimensional parameters that may require attention and tuning. If a window of dimensions i,j is used, the block pattern may need prior knowledge of i and j. In this example, i and j correspond to the range of sensors and of the timestamps that suffered loss, respectively.

However, many possible patterns of loss are possible in a given window. Embodiments of the invention may determine which instances of these patterns are representative in the domain such that, during online operation, the pattern recognition engine scans for those instances of the patterns.

Focusing on specific patterns may make the process of searching for or identifying patterns during the online stage more manageable and effective. Embodiments of the invention are not limited to searching for specific patterns, however.

Offline Stage

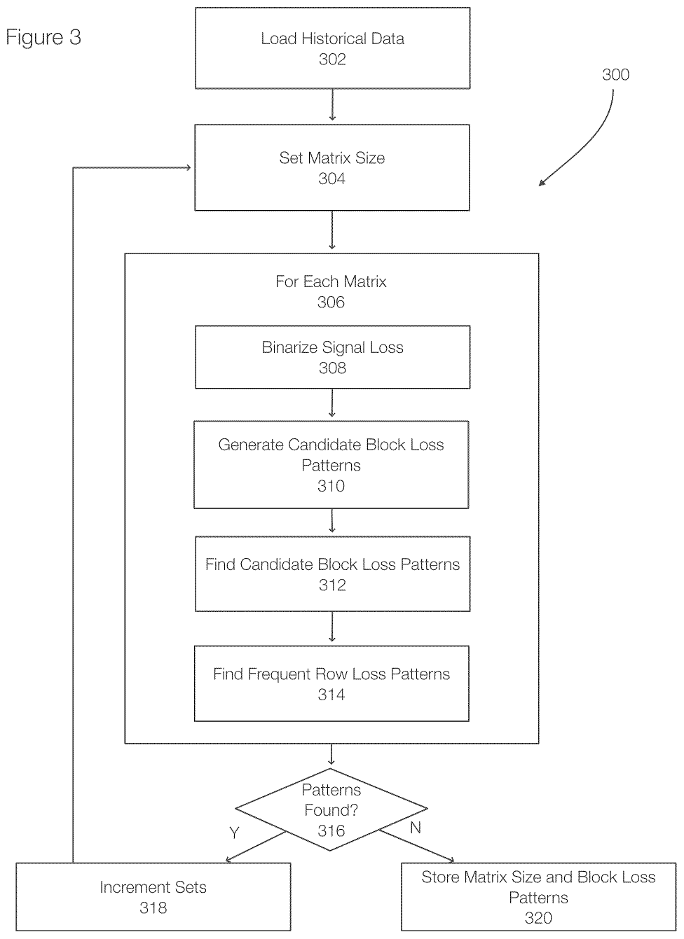

FIG. 3 discloses aspects of a method of searching for loss patterns in historical data in preparation for an online stage. The method 300 may begin by loading 302 historical data. In one example, the historical data includes information or data from all n sensors that will be available during an online stage. The method 300 will be discussed with respect to FIGS. 3-5B.

The method 300 generally represents an offline stage of the imputation pipeline. The offline stage generally involves using historical data or historical observations to search for or to learn loss patterns of the digital twin system. Once the loss patterns are learned from or identified in the historical data, the online stage uses these patterns to search data generated during the online stage. When loss patterns are found, a data imputation method may be selected and used to impute values for the missing values.

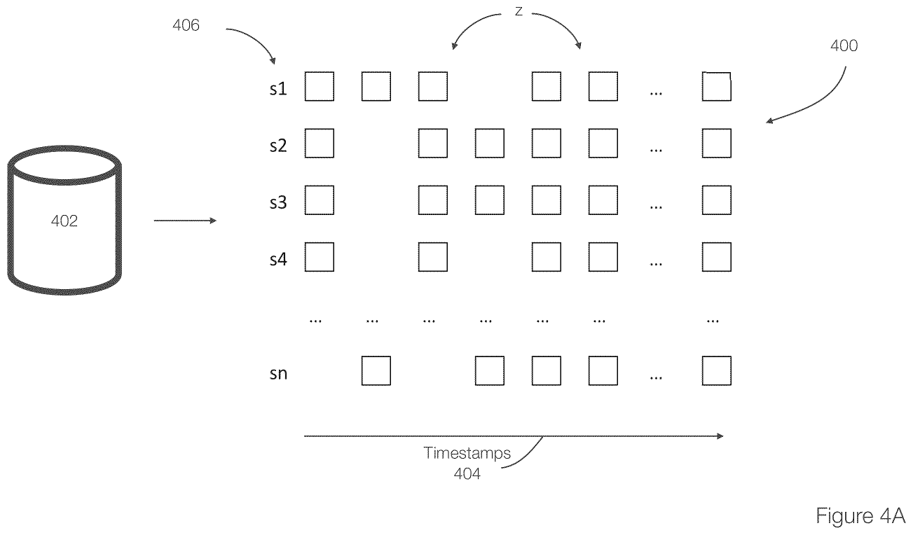

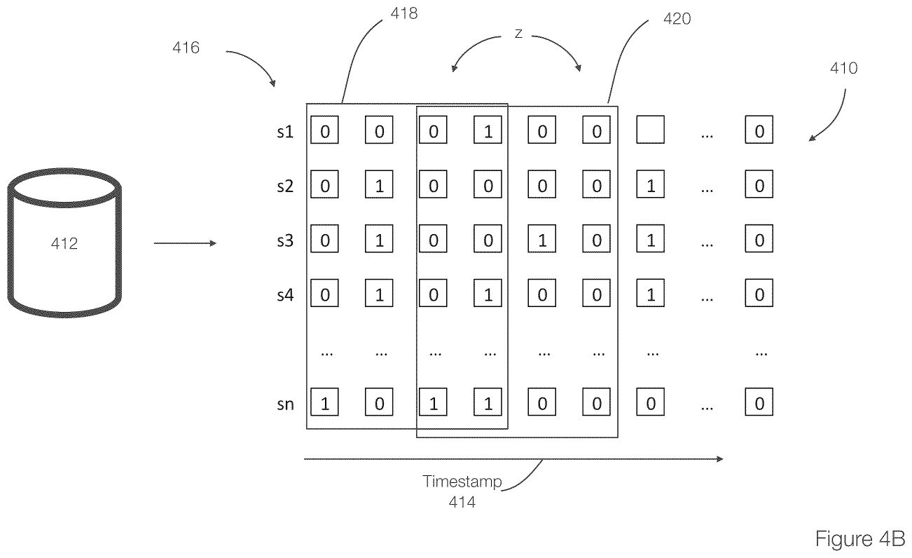

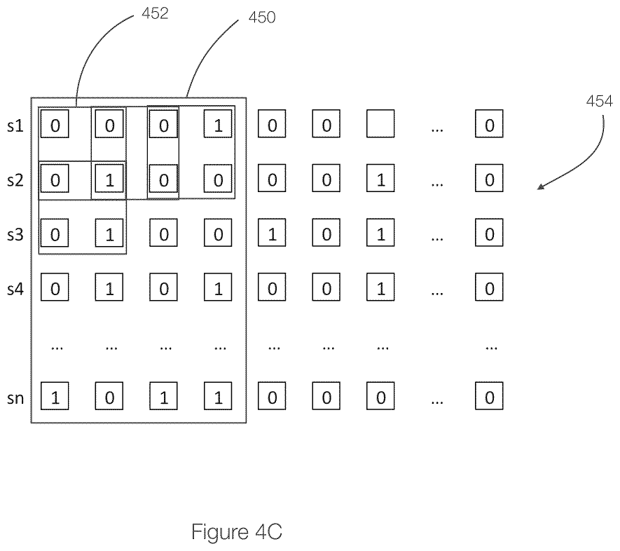

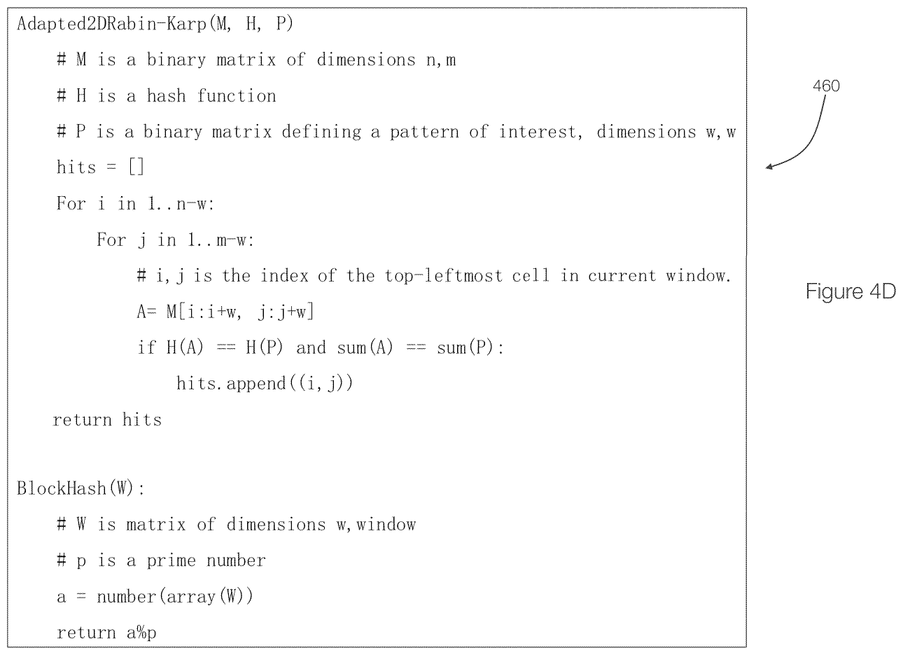

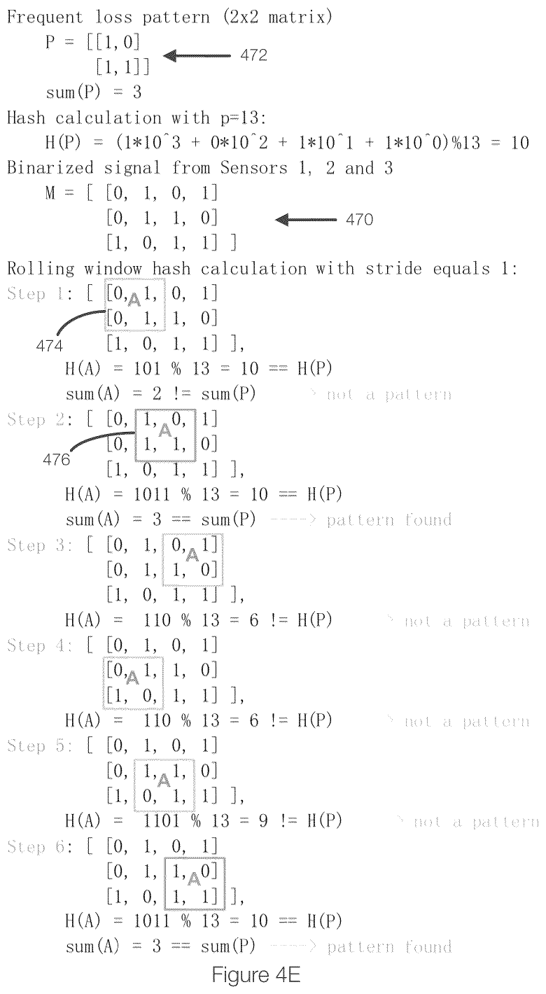

FIG. 4A illustrates an example of historical data 400 that may be stored in a database 402. The data 400 illustrates data for a series of n sensors (s₁ . . . sₙ). The data 400 includes observations z. Each of the sensors 406 may be associated with large numbers of samples or observations. Each sensor may be associated with a series of observations. In FIG. 4A, the values of the observations in these series are not illustrated, but the z observations illustrate that some values in the series of data are missing.

Because the data 400 may be large (e.g., z is large), the full range of data may be evaluated using matrices M. The z observations can be split into several matrices M. Each of the matrices M can be scanned for patterns in a parallel manner.

Once the historical data is loaded 302, a matrix size may be determined. In some examples, the data 400 may be evaluated using multiple matrices of different sizes. The matrix may or may not be square. However, the number of rows in the matrix is usually set to be the number of sensors in the domain. FIG. 4A illustrates n sensors. The number of observations included in a matrix M may be set to m, which may be set arbitrarily. Thus, the matrix size is n×m in one example. FIG. 4A further illustrates that the observations z are also associated with timestamps 404.

FIG. 4B illustrates another example of data 410 from a database 412. The observations z from sensors 416 are associated with timestamps 414. In this example, the observations z have been binarized to represent signal loss. In this example, a 1 represents a signal loss and a 0 represents a valid value.

FIG. 4B also illustrates a matrix size of n×4. In this example, two overlapping matrices 418 and 420 are illustrated with an overlap of m/2 or 2 in this example. The overlap may impact the ability to detect patterns. If the matrices 418 and 420 have no overlap, the cost may be missing a few patterns that happen in these arbitrarily defined boundary regions of the matrices. However, the number of matrices can impact processing time. The number of matrices may depend on the number of observations.

In one example, the values of the sensors 416 may be disregarded at least because embodiments of the invention are searching for or learning loss patterns. Thus, the values are changed or binarized to either 0 or 1 depending on signal presence/loss and the data 410 is then processed using the matrices.

Once the matrix size is set 304, similar steps or acts are performed 306 for each matrix and these steps or acts may be performed in parallel. Initially, each matrix is binarized 308 as previously described. For each matrix, sets P_{b} and Pᵣ are initialized to be empty. These sets will collect block loss patterns P_{b} that are identified and frequent row loss patterns Pᵣ, respectively.

In the method 300, after the sets P_{b} and Pᵣ for the block loss patterns and row loss patterns are set and the observations are binarized, candidate block loss patterns are generated 310. This includes generating candidate patterns whose size fits into the dimensions of the matrix M. For example, for a matrix whose size is 4×4, the patterns include 2×2, 2×3, 3×2, and 3×3. The minimum size of the window or pattern is 2×2 and the maximum is the size of the matrix-1. Thus, the maximum window size for a 4×4 matrix is 3×3 window.

As previously stated, the set P_{b} is used to collect candidate patterns and is initially empty. The set Pᵣ is initially empty initially and is used to collect frequent row loss patterns. These two matrices P_{b} and Pᵣ are for the current matrix size being considered.

For the block loss pattern, all candidate block loss patterns (candidate patterns) whose size fits into the dimensions of the matrix M are generated and embodiments of the invention then search the matrices for the candidate patterns.

In one example, the candidate patterns are generated as follows. A block or window, whose size may be w×w, is generated and the matrix is evaluated by moving the window over the entries in the matrix. Multiple windows may be used. The value of w can range from 2 up to size of the current matrix-1. Sizing the window in this manner prevents whole row or whole column losses from being addressed as part of the block pattern losses. Rather, whole row and/or whole column losses are addressed as a missing value pattern instead of a block pattern. Further, the candidate patterns are not limited to square windows, but may also use rectangular windows. For example, a matrix whose size is 3×3 may be searched for patterns. Considering a block or window size of 2×2, there are four possible patterns. In this case, a pattern is detected when all of the values inside the window are missing values or 1s (because of being binarized). The pattern stored may be the matrix being searched. More specifically, a 2×2 window is used to search a 3×3 matrix, which results in 4 windows that will be evaluated for a pattern. In one example and as different window sizes are used, block loss patterns are detected.

When generating the candidate patterns, patterns previously searched to not need to be searched a second time. For example, if a 2×2 pattern is found, the pattern may not need to be searched again. In one example, a set [symbol] , which is initially empty, may be used to store patterns that have already been learned or identified. Any pattern in [symbol] does not need to be considered again. When new candidate patterns are generated for the current matrix size, they are added to [symbol] and will only be tested in the current iteration of matrix size. As the search matrix is enlarged, the possible patterns are also increased and might be redundant if there were not stored earlier. For example, if a 2×2 pattern is found in a matrix size of 3×3, the 2×2 pattern does not need to be searched when the matrix size is increased to 4×4.

In one example, once the candidate patterns have been identified, candidate block loss patterns are found 312 in the data. Finding 312 the candidate block loss patterns in the historical data may include performing pattern matching over the binarized matrices.

FIG. 4C discloses aspects of finding block loss patterns using a window. FIG. 4C illustrates data or observations 454 that has been binarized. Further, matrices having a size of n×4 are established, and which may overlap as illustrated in FIG. 4B. FIG. 4C illustrates a matrix 450 and a window 452 that is used to search for block loss patterns in the matrix 450 and stored in the set P_{b}. As illustrated, the window 452 may iterate over the matrix 450 and evaluate different groups of the binarized entries to find block loss patterns. In effect, the window 452 is a rolling window. Different sized searching windows may be used, depending on the patterns found during the offline stage.

In one example, an adapted 2D Rabin-Karp method is used to perform pattern matching. The method is adapted for a matrix or window rather than a string. In this example, signal loss is marked as a 1 and a valid signal value is marked as a 0. The alphabet used in the adapted Rabin-Karp method includes two symbols.

Further, embodiments of the invention consider loss patterns in sets of sensors over time, rather than a single sensor. As illustrated in FIG. 4C, the window 452 may consider 2 sensors. Larger windows may consider additional sensors. Further, the window rolls through the matrix 450 and thus considers the binarized values for all n sensors. In one embodiment, the largest window for the matrix 452 is (n−1)×3 or 3×3 if a square window. Whole row or column losses are determined separately in one embodiment.

FIG. 4D illustrates pseudocode for an adapted rabin-karp method. In the pseudocode or method 460, M is a binary matrix, whose dimensions are n and m. H is a hash function. P is a binary matrix defining a pattern of interest and whose dimensions are w×w. Thus, P is an example of a searching window. The hits are stored by the method 460.

The method 460 includes moving the window iteratively over the matrix M, which includes binarized sensor signal, to check for a pattern P in square windows of size w (the size of the pattern). The current window being checked is labeled A in this example.

The hash function H may, for example, interpret the value of a matrix as a decimal value and compute the module of that value by a predetermined prime number p. If it is necessary to resolve hash conflicts, these conflicts may be resolved by checking whether the sum of values in the current window A is equal to the sum of signal losses included in the pattern P.

FIG. 4E illustrates an example of searching for a block loss pattern in a matrix. FIG. 4E illustrates searching for a certain pattern. In some embodiments, however, only patterns that were found during the offline stage are searched and these patterns typically include windows will all 1s (missing values). FIG. 4E illustrates how such a pattern may be found. In FIG. 4E, the matrix 470 is searched using a pattern 472 and a window 474. In step 1, the window 474 (current window A) is placed in the matrix 470 and the binarized values in the window 474 are evaluated to determine whether the window matches the loss pattern 472. To determine whether there is a match, the hash of the pattern 472 is determined and the sum of the binarized values may also be used. The hash of the pattern, in this example, is H(P)=10. The sum of the pattern is sum(P)=3.

In step 1, the hash of the window 474 equals the hash of the pattern 472. Thus, H(A)=H(P) suggests a match. There may be a conflict, however, even when the hashes are equal. This conflict is resolved using the sum. Because sum(A) is not equal to sum(P), the loss pattern 472 is not found in the window 474.

In step 2, the window moves to a new position in the matrix 470 and is referred to as the window 476 for clarity. The hash and the sum of the window are evaluated. In step 2, H(A)=H(P) and sum(A)=sum(P). As a result, the pattern 472 is found in step 2 and the hits is increased from 0 to 1. Each time a pattern is found, the hits is increased.

In step 3, H(A) is not equal to H(P). As a result, a pattern is not found, and the sum(A) does not need to be determined or used to determine whether a pattern match is present or not. A similar process is performed as the window iterates over the matrix 470. The pattern 472 is found a second time in step 6 in this example and hits is incremented to 2.

In the example of FIG. 4E, the hash calculation is performed at each step and the stride of the window is one. In other words, the window is moved one observation displacement at a time. For larger window sizes, larger strides may be parameterized.

This may be repeated for all of the candidate patterns and all patterns found are added to the set P_{b}. The number of hits may be included as an annotation. In this example, the pattern 472 is included in the set P_{b} with an annotation of 2 hits. This frequency or the number of hits may be used to determine if the pattern is relevant to the domain. For example, if most patterns in the set P_{b} have a number of hits higher than a threshold value (e.g., 5), patterns with a number of hits less than 5 or less than 3, by way of example, may not be relevant to the domain.

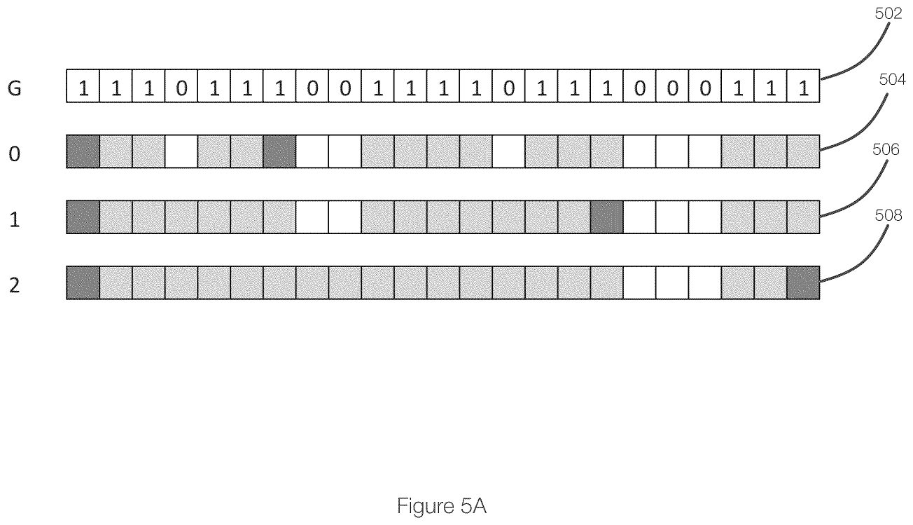

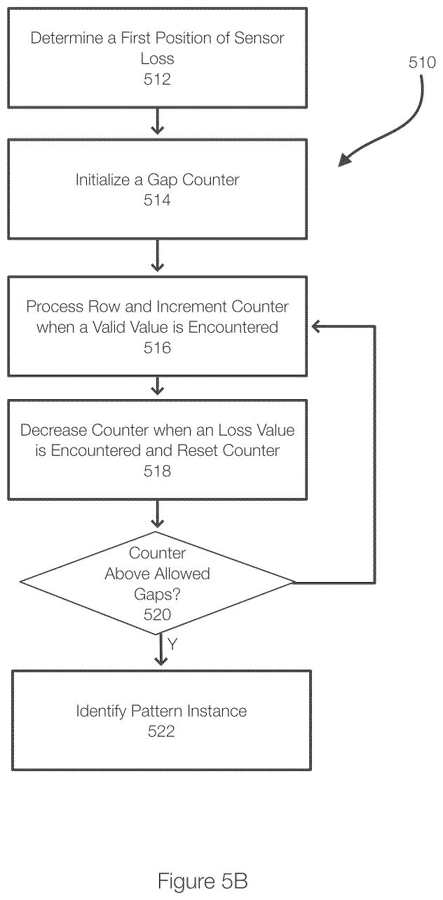

After block loss patterns have been found 312, row loss patterns are found 314. FIG. 5A discloses aspects of finding 312 row loss patterns. FIG. 5A illustrates a row 502 of binarized values or observations. The column G represents aspects of searching for row loss patterns in the context of a maximum allowed gap. The row 504 is associated with a maximum allowed gaps of 0, the row 506 is associated with a maximum allowed gaps of 1, and the row 508 is associated with a maximum allowed gap of 3.

In one example, a frequent loss patterns may be characterized by an intermittent sensor signal loss, with even or uneven gaps. To identify row loss patterns, the observations are searched based on a maximum allowed gap.

In the row 504, no gaps are allowed. This may be appropriate for situations where a single signal value is useful for decision making purposes. In the row 504, five sequences (shaded areas corresponding to 1s) of loss are detected and are separated by 4 sets (unshaded portions corresponding to 0s) of valid observations. For each of the rows 504, 506, and 508, the heavier shaded blocks identify points at which a frequent row loss pattern can be identified. In one example, any two consecutive sequences of loss configure a frequent row loss pattern instance.

In the row 506, which has an allowed gap of 1, the frequent loss pattern is identified later, with larger sequences of loss considered, notwithstanding the allowed gaps of a single value. In the row 508, which has an allowed gap of 2, the entire width of the matrix is considered to contain a frequent row loss instance. If FIG. 5A were considered with an allowed gap of 3, the entire window is considered a single sequence of signal loss and does not characterize the frequent row loss pattern.

During the offline stage, embodiments search for frequent row loss patterns to determine whether matrixes of a certain size contain relevant numbers of frequent row loss instances.

FIG. 5B discloses aspects of searching for row loss patterns. In one example, for each row in the matrix (e.g., each sensor in the sensor set), the first position of sensor or signal loss (the first 1) is determined 512 and a gap counter is initialized 514. Each row is processed. The counter is incremented 516 when a valid or signal value (e.g., a 0) is encountered and the counter is decreased 518 or zeroed or reset when a loss (e.g., a 1) is detected.

If the counter is above the allowed gaps value (if the counter is above the allowed gaps value (Y at 520), a pattern instance is identified 522. Otherwise (N at 520), the evaluation of the binarized array continues.

For example, a sensor may have the follow sequence: [1010010001]. Embodiments of the invention find these types of patterns based on a number of valid signals, represented by 0s. This is a gap in signal losses.

When the gap value is set at 2, the method 500 is interrupted (Y at 520) at the ninth signal ([101001000], which indicates that the gap counter is above the allowed value of 2). The pattern returned in this example is: [101001].

If the maximum gap value is 1, the pattern returned in this example is as the loop would have been broken at the 5^{th} value or at [10100].

The method 510 allows a single frequent loss pattern to be found in the same window. Identified row loss patterns are stored in the set Pᵣ.

Returning to FIG. 3, the sets P_{b} and Pᵣ can be analyzed to determine whether relevant patterns have been found 316. In one example, this is based on the cardinality of these sets. If the cardinality is above a predetermined threshold, sufficient patterns are found. If relevant patterns are found (Y at 316), then the sets are incremented 318. For example, [symbol] _{b}= [symbol] _{b}∪P_{b}. This adds the loss patterns found for the current matrix to be added to the larger set of loss patterns for all matrix sizes. More specifically, embodiments of the invention use these sets to determine whether relevant patterns were detected in matrices of size n×m. This may be achieved using the cardinality.

If relevant patterns are not found (N at 316), the matrix size and block loss patterns are stored 320. In this example, if relevant patterns are not found within a certain window, it is less likely that a pattern will emerge within a larger window. Thus, the search is interrupted at 320 when loss patterns are not found in a matrix.

Embodiments of the invention find the maximum matrix size that contains relevant patterns in one example. Generating larger matrix sizes may reduce the computing resources required to determine relevant patterns and to ensure that a suitable maximum matrix size is obtained. If no relevant patterns are found within a certain window, it is unlikely that patters will emerge within a larger window. The matrix size used for searching during the online stage is the largest matrix size for which relevant patterns were found in the offline stage. In addition, an optimized window size, which is the smallest window that accounts for representative large patterns is also useful.

If relevant patterns are found, the matrix width m is increased 306. The increment in size may vary and follow different rules. In one example, the matrix size is doubled for each iteration (4, 8, 16, 32, 64, . . . ).

If no patterns exist in the matrix size m, the previous value of m is used for determining the size of the matrix for the online stage. The set [symbol] _{b} is also stored.

Online Stage

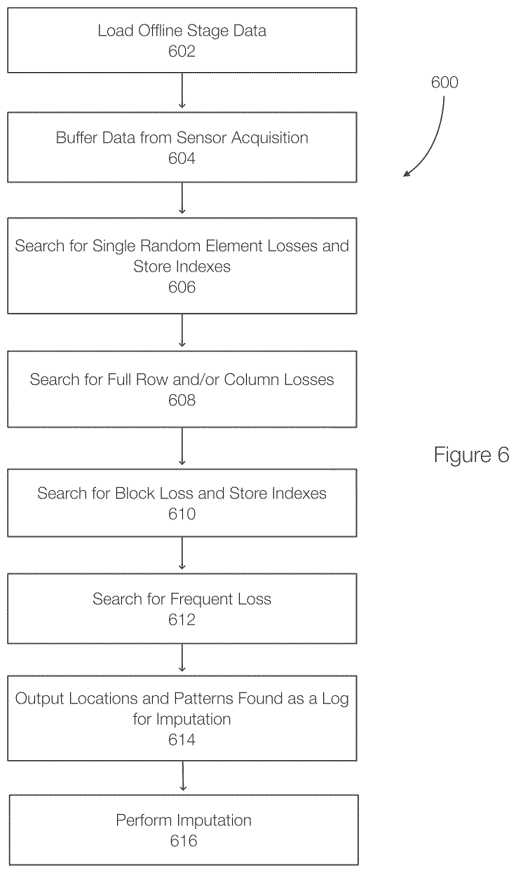

FIG. 6 discloses aspects of an online stage for observation imputation. During the online stage, the method 600 loads 602 data from the offline state, which includes the data loss patterns (both block and row loss patterns). More specifically, the maximum matrix size n, m, the maximum gap value for frequent row losses, and block loss patterns [symbol] _{b} are loaded 602. Next, data is buffered 604 from the sensors. In other words, sensor data or observations are acquired and buffered. In one example, m time intervals are buffered, which relates to the matrix size m. In the next iteration, m-o intervals are buffered, where o is the size of the overlap between matrices. This data is used to generate a binarized matrix n,m as previously described.

The method 600 the searches 606 for random element losses and stores the indexes into the buffered data. This may be performed using a rolling 3×3 window and focusing on the center element. If there are no more than two adjacent loss elements, the center loss is considered a random element loss and its index is stored.

Next, a search is performed 608 for full row and/or full column losses. A full row sensor loss indicates that the sensor is turned-off or the like. A full column loss indicates that signals are not arriving in a timely manner.

Using the block loss patterns [symbol] _{b}, the acquired observations are searched 610. When a pattern is found, each pattern is indexed. The acquired observations are also searched 612 for frequent row loss patterns and indexes of all the frequent row loss pattern instances are stored.

Locations and patterns found in the acquired observations are output 614 as a log. Imputation is then performed 616. Performing imputation includes selecting an imputation method based on the detected loss patterns. More specifically, the output at 614 may include loss patterns that were detected in the observations. This allows missing values to be imputed based on the type of loss pattern.

In one example, spatial imputation is performed. Spatial imputation relies on spatial correlation between sensor nodes. This allows nearest neighbors and association rules allows values to be imputed. Temporal imputation relies on the time of correlations of the same node or sensor. Values are imputed using time series forecasting or regression methods. Values can be imputed using spatial and/or temporal imputation. Providing the index, which was previously stored, allows the relevant values to be imputed.

Embodiments of the invention increase the resilience of a digital twin by informing imputation methods. Relevant loss patterns are detected during operation and allows values to be imputed for the detected loss patterns.

Embodiments of the invention, such as the examples disclosed herein, may be beneficial in a variety of respects. For example, and as will be apparent from the present disclosure, one or more embodiments of the invention may provide one or more advantageous and unexpected effects, in any combination, some examples of which are set forth below. It should be noted that such effects are neither intended, nor should be construed, to limit the scope of the claimed invention in any way. It should further be noted that nothing herein should be construed as constituting an essential or indispensable element of any invention or embodiment. Rather, various aspects of the disclosed embodiments may be combined in a variety of ways so as to define yet further embodiments. Such further embodiments are considered as being within the scope of this disclosure. As well, none of the embodiments embraced within the scope of this disclosure should be construed as resolving, or being limited to the resolution of, any particular problem(s). Nor should any such embodiments be construed to implement, or be limited to implementation of, any particular technical effect(s) or solution(s). Finally, it is not required that any embodiment implement any of the advantageous and unexpected effects disclosed herein.

It is noted that embodiments of the invention, whether claimed or not, cannot be performed, practically or otherwise, in the mind of a human. Accordingly, nothing herein should be construed as teaching or suggesting that any aspect of any embodiment of the invention could or would be performed, practically or otherwise, in the mind of a human. Further, and unless explicitly indicated otherwise herein, the disclosed methods, processes, and operations, are contemplated as being implemented by computing systems that may comprise hardware and/or software. That is, such methods processes, and operations, are defined as being computer-implemented.

The following is a discussion of aspects of example operating environments for various embodiments of the invention. This discussion is not intended to limit the scope of the invention, or the applicability of the embodiments, in any way.

In general, embodiments of the invention may be implemented in connection with systems, software, and components, that individually and/or collectively implement, and/or cause the implementation of, digital twin system operations, including loss pattern identification operations, loss pattern detection operations, and/or imputation method selection operations, and imputation operations.

Example cloud computing environments, which may or may not be public, include storage environments that may provide data protection functionality for one or more clients. Another example of a cloud computing environment is one in which processing, data protection, and other, services may be performed on behalf of one or more clients. Some example cloud computing environments in connection with which embodiments of the invention may be employed include, but are not limited to, Microsoft Azure, Amazon AWS, Dell EMC Cloud Storage Services, and Google Cloud. More generally however, the scope of the invention is not limited to employment of any particular type or implementation of cloud computing environment.

In addition to the cloud environment, the operating environment may also include one or more clients that are capable of collecting, modifying, and creating, data. As such, a particular client may employ, or otherwise be associated with, one or more instances of each of one or more applications that perform such operations with respect to data. Such clients may comprise physical machines, containers, or virtual machines (VMs).

Particularly, devices in the operating environment may take the form of software, physical machines, containers, or VMs, or any combination of these, though no particular device implementation or configuration is required for any embodiment. Similarly, data system components such as databases, storage servers, storage volumes (LUNs), storage disks, replication services, backup servers, restore servers, backup clients, and restore clients, for example, may likewise take the form of software, physical machines containers, or virtual machines (VMs), though no particular component implementation is required for any embodiment.

As used herein, the term ‘data’ is intended to be broad in scope. Data includes sensor data, observations, time series data, binarized values, or the like or combination thereof.

Example embodiments of the invention are applicable to any system capable of storing and handling various types of objects, in analog, digital, or other form.

It is noted that any of the disclosed processes, operations, methods, and/or any portion of any of these, may be performed in response to, as a result of, and/or, based upon, the performance of any preceding process(es), methods, and/or, operations. Correspondingly, performance of one or more processes, for example, may be a predicate or trigger to subsequent performance of one or more additional processes, operations, and/or methods. Thus, for example, the various processes that may make up a method may be linked together or otherwise associated with each other by way of relations such as the examples just noted. Finally, and while it is not required, the individual processes that make up the various example methods disclosed herein are, in some embodiments, performed in the specific sequence recited in those examples. In other embodiments, the individual processes that make up a disclosed method may be performed in a sequence other than the specific sequence recited.

Following are some further example embodiments of the invention. These are presented only by way of example and are not intended to limit the scope of the invention in any way.

Embodiment 1. A method comprising: identifying loss patterns from historical observations, the loss patterns including block loss patterns and row loss patterns during an offline stage, searching for the loss patterns in online observations collected during an online stage, selecting an imputation method for each of the loss patterns found in the online observations, and imputing values for missing values the observations corresponding to the loss patterns found in the online observations.

Embodiment 2. The method of embodiment 1, further comprising binarizing the historical observations.

Embodiment 3. The method of embodiment 1 and/or 2, further identifying the loss patterns using a matrix.

Embodiment 4. The method of embodiment 1, 2, and/or 3, further comprising generating candidate block loss patterns.

Embodiment 5. The method of embodiment 1, 2, 3, and/or 4, further comprising finding the candidate block loss patterns in the historical observations by iterating over observations in the matrix using with a window.

Embodiment 6. The method of embodiment 1, 2, 3, 4, and/or 5, wherein a loss pattern is found when a hash of a candidate block loss pattern matches a hash of a window and a sum of the candidate block loss pattern matches a sum of the window.

Embodiment 7. The method of embodiment 1, 2, 3, 4, 5, and/or 6, further comprising finding the row loss patterns based on one or more allowed gaps.

Embodiment 8. The method of embodiment 1, 2, 3, 4, 5, 6, and/or 7, further comprising storing the block loss patterns and the row loss patterns that are found in the historical observations.

Embodiment 9. The method of embodiment 1, 2, 3, 4, 5, 6, 7, and/or 8, further comprising finding additional block loss patterns based on a new matrix size; and increasing a size of the matrix until no more loss patterns are found, wherein a recent size of the matrix is used in the online stage.

Embodiment 10. The method of embodiment 1, 2, 3, 4, 5, 6, 7, 8, and/or 9, further comprising searching for random element losses and searching for full row and/or full column losses.

Embodiment 11. A method for performing any of the operations, methods, or processes, or any portion of any of these, or any combination thereof disclosed herein.

Embodiment 12. A non-transitory storage medium having stored therein instructions that are executable by one or more hardware processors to perform operations comprising the operations of any one or more of embodiments 1-11.

The embodiments disclosed herein may include the use of a special purpose or general-purpose computer including various computer hardware or software modules, as discussed in greater detail below. A computer may include a processor and computer storage media carrying instructions that, when executed by the processor and/or caused to be executed by the processor, perform any one or more of the methods disclosed herein, or any part(s) of any method disclosed.

As indicated above, embodiments within the scope of the present invention also include computer storage media, which are physical media for carrying or having computer-executable instructions or data structures stored thereon. Such computer storage media may be any available physical media that may be accessed by a general purpose or special purpose computer.

By way of example, and not limitation, such computer storage media may comprise hardware storage such as solid state disk/device (SSD), RAM, ROM, EEPROM, CD-ROM, flash memory, phase-change memory (“PCM”), or other optical disk storage, magnetic disk storage or other magnetic storage devices, or any other hardware storage devices which may be used to store program code in the form of computer-executable instructions or data structures, which may be accessed and executed by a general-purpose or special-purpose computer system to implement the disclosed functionality of the invention. Combinations of the above should also be included within the scope of computer storage media. Such media are also examples of non-transitory storage media, and non-transitory storage media also embraces cloud-based storage systems and structures, although the scope of the invention is not limited to these examples of non-transitory storage media.

Computer-executable instructions comprise, for example, instructions and data which, when executed, cause a general-purpose computer, special purpose computer, or special purpose processing device to perform a certain function or group of functions. As such, some embodiments of the invention may be downloadable to one or more systems or devices, for example, from a website, mesh topology, or other source. As well, the scope of the invention embraces any hardware system or device that comprises an instance of an application that comprises the disclosed executable instructions.

Although the subject matter has been described in language specific to structural features and/or methodological acts, it is to be understood that the subject matter defined in the appended claims is not necessarily limited to the specific features or acts described above. Rather, the specific features and acts disclosed herein are disclosed as example forms of implementing the claims.

As used herein, the term module, component, agent, client, or engine may refer to software objects or routines that execute on the computing system. The different components, modules, agents, clients, engines, and services described herein may be implemented as objects or processes that execute on the computing system, for example, as separate threads. While the system and methods described herein may be implemented in software, implementations in hardware or a combination of software and hardware are also possible and contemplated. In the present disclosure, a ‘computing entity’ may be any computing system as previously defined herein, or any module or combination of modules running on a computing system.

In at least some instances, a hardware processor is provided that is operable to carry out executable instructions for performing a method or process, such as the methods and processes disclosed herein. The hardware processor may or may not comprise an element of other hardware, such as the computing devices and systems disclosed herein.

In terms of computing environments, embodiments of the invention may be performed in client-server environments, whether network or local environments, or in any other suitable environment. Suitable operating environments for at least some embodiments of the invention include cloud computing environments where one or more of a client, server, or other machine may reside and operate in a cloud environment.

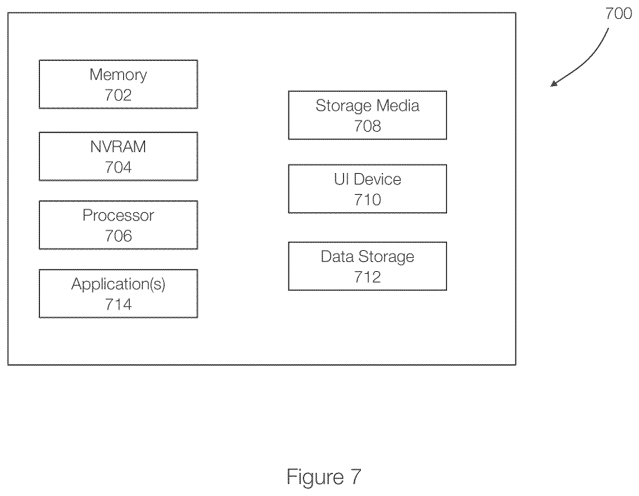

With reference briefly now to FIG. 7, any one or more of the entities disclosed, or implied, by the Figures, and/or elsewhere herein, may take the form of, or include, or be implemented on, or hosted by, a physical computing device, one example of which is denoted at 700. As well, where any of the aforementioned elements comprise or consist of a virtual machine (VM), that VM may constitute a virtualization of any combination of the physical components disclosed in FIG. 7.

In the example of FIG. 7, the physical computing device 700 includes a memory 7020 which may include one, some, or all, of random access memory (RAM), non-volatile memory (NVM) 704 such as NVRAM for example, read-only memory (ROM), and persistent memory, one or more hardware processors 706, non-transitory storage media 708, UI device 710, and data storage 712. One or more of the memory components 702 of the physical computing device 700 may take the form of solid-state device (SSD) storage. As well, one or more applications 714 may be provided that comprise instructions executable by one or more hardware processors 706 to perform any of the operations, or portions thereof, disclosed herein.

Such executable instructions may take various forms including, for example, instructions executable to perform any method or portion thereof disclosed herein, and/or executable by/at any of a storage site, whether on-premises at an enterprise, or a cloud computing site, client, datacenter, data protection site including a cloud storage site, or backup server, to perform any of the functions disclosed herein. As well, such instructions may be executable to perform any of the other operations and methods, and any portions thereof, disclosed herein.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method comprising:
identifying loss patterns from historical observations, the loss patterns including block loss patterns and row loss patterns during an offline stage;
searching for the loss patterns in online observations collected during an online stage;
selecting an imputation method for each of the loss patterns found in the online observations; and
imputing values for missing values the observations corresponding to the loss patterns found in the online observations.

2. The method of claim 1, further comprising binarizing the historical observations.

3. The method of claim 1, further identifying the loss patterns using a matrix.

4. The method of claim 3, further comprising generating candidate block loss patterns.

5. The method of claim 4, further comprising finding the candidate block loss patterns in the historical observations by iterating over observations in the matrix using with a window.

6. The method of claim 5, wherein a loss pattern is found when a hash of a candidate block loss pattern matches a hash of a window and a sum of the candidate block loss pattern matches a sum of the window.

7. The method of claim 3, further comprising finding the row loss patterns based on one or more allowed gaps.

8. The method of claim 7, further comprising storing the block loss patterns and the row loss patterns that are found in the historical observations.

9. The method of claim 3, further comprising finding additional block loss patterns based on a new matrix size; and increasing a size of the matrix until no more loss patterns are found, wherein a recent size of the matrix is used in the online stage.

10. The method of claim 1, further comprising searching for random element losses and searching for full row and/or full column losses.

11. A non-transitory storage medium having stored therein instructions that are executable by one or more hardware processors to perform operations comprising:
identifying loss patterns from historical observations, the loss patterns including block loss patterns and row loss patterns during an offline stage;
searching for the loss patterns in online observations collected during an online stage;
selecting an imputation method for each of the loss patterns found in the online observations; and
imputing values for missing values the observations corresponding to the loss patterns found in the online observations.

12. The non-transitory storage medium of claim 11, further comprising binarizing the historical observations.

13. The non-transitory storage medium of claim 11, further identifying the loss patterns using a matrix.

14. The non-transitory storage medium of claim 13, further comprising generating candidate block loss patterns.

15. The non-transitory storage medium of claim 14, further comprising finding the candidate block loss patterns in the historical observations by iterating over observations in the matrix using with a window.

16. The non-transitory storage medium of claim 15, wherein a loss pattern is found when a hash of a candidate block loss pattern matches a hash of a window and a sum of the candidate block loss pattern matches a sum of the window.

17. The non-transitory storage medium of claim 13, further comprising finding the row loss patterns based on one or more allowed gaps.

18. The non-transitory storage medium of claim 17, further comprising storing the block loss patterns and the row loss patterns that are found in the historical observations.

19. The non-transitory storage medium of claim 13, further comprising finding additional block loss patterns based on a new matrix size; and increasing a size of the matrix until no more loss patterns are found, wherein a recent size of the matrix is used in the online stage.

20. The non-transitory storage medium of claim 11, further comprising searching for random element losses and searching for full row and/or full column losses.
